(19) United States
(12) Patent Application Publication
(10) Pub. No.: US 2008/0129311 A1
(43) Pub. Date: Jun. 5, 2008

(54) ARRANGEMENT FOR MONITORING A BOLT CONNECTION

(76) Inventors: Johann Schuster, Oberasbach (DE); Stefan Stocker, Grossenseebach (DE)

Correspondence Address: SCHIFF HARDIN, LLP;PATENT DEPARTMENT, 6600 SEARS TOWER, CHICAGO, IL, 60606-6473, US

(21) Appl. No.: 11/945,319

(22) Filed: Nov. 27, 2007

(30) Foreign Application Priority Data
Nov. 27, 2006 (DE) 10 2006 055 929.0

(51) Int. Cl. G01R 31/04

(52) U.S. Cl. 324/538

(57) ABSTRACT

An arrangement monitors a bolt connection, formed with a first component and a second component that are connected with one another by being held between the two retainer elements of the bolt connection. The arrangement has an insulator with two electrical contacts and a spring arrangement located between one of the retainer elements of the bolt connection on one side and the first or second component that is closer thereto on the other side. The spring arrangement is arranged between the two electrical contacts such that the two contacts are electrically separated by its predetermined spring force given a loose bolt connection and such that, given a firm bolt connection, the two contacts are electrically in contact with one another due to overcoming the spring tension. The two contacts are connected with an electronic monitoring circuit that indicates a firm bolt connection as long as the electrical contact exists.

### BACKGROUND OF THE INVENTION

1. Field of the Invention

The invention concerns an arrangement for monitoring a bolt connection.

2. Description of the Prior Art

Bolt connections that are subjected to mechanical loads loosen unless suitable countermeasures are taken. Depending on the intended use, loose bolt connections can cause great damage.

For example, gradient coils in magnetic resonance apparatuses for medical applications are operated with a temporally varying current of up to 650 amperes. Current-supplying conductors are connected with the gradient coils via bolt connections. Vibrations that are caused by dynamic currents in the static magnetic field (Lorentz forces) act on these bolt connections. Given a loosening of the bolt connection, its contact resistance is increased. An overheating or a melting of the bolt connection ensues due to the high current strength, and in the worst case this can lead to burning.

To avoid damage, bolt connections are tightened with a torque wrench until a predetermined torque is achieved. A defined mechanical initial loading of the bolt connection that prevents a loosening due to forces acting on the bolt connection is produced by the torque.

In the case of a damaged threading or a tight thread pitch, however, it is possible for a torque wrench to release early without reaching the predetermined torque.

Torque wrenches must be calibrated regularly in a complicated manner. If unacceptable deviations are detected in the calibration, bolt connections of already-mounted systems must possibly be inspected at high cost in the event that this is possible at all.

### SUMMARY OF THE INVENTION

An object of the present invention is to provide an arrangement with which the reliability of a bolt connection can be monitored with low expenditure of cost and time.

This object is achieved in accordance with the invention by an arrangement for monitoring a bolt connection having two retainer elements that hold a first component and a second component therebetween, that are connected with one another by the bolt connection. The arrangement includes an insulator having two electrical contacts and a spring arrangement that are located between one of the retainers of the bolt connection on one side and the first or second component that is closer thereto on the other side. The spring arrangement is located between the two electrical contacts so that the two contacts are electrically separated by its predetermined spring force given a loose bolt connection. Given a firm bolt connection, the two contacts are electrically connected with one another by overcoming the spring force. The two contacts are connected with an electronic monitoring circuit that indicates the firm bolt connection.

The inventive arrangement is suitable for remotely monitoring the stability of critical bolt connections of a general type.

It is particularly suitable for bolt connections that are under mechanical loads and that are simultaneously fed with current. The consequences described above of a dangerous overheating are avoided since unreliable bolt connections can already be detected in advance, such as before operation involving a current feed as well as during such operation.

The inventive arrangement is also particularly suitable for bolt connections that are used for connection of gradient coils in magnetic resonance apparatuses. Here a subsequent tightening of unreliable bolt connections would only be possible at high cost and expenditure of time.

Monitoring of bolt connections in filter plates of a magnetic resonance apparatus, or in connections to a gradient power amplifier (GPA) is also possible.

Human errors or manufacturing errors in the tightening of a bolt connection are promptly detected and the disadvantageous consequences associated therewith are precluded in advance.

Connections that loosen under load and vibration during operation are detected.

It is likewise possible to largely forego the use of torque wrenches as well as their calibration since the reaching of the defined minimum initial load is indicated by the electrical connection of the contacts.

### BRIEF DESCRIPTION OF THE DRAWINGS

FIG. 1 shows an exemplary embodiment of the inventive arrangement with loose bolt connection.

FIG. 2 shows the embodiment of FIG. 1 but with a firm bolt connection.

FIG. 3 shows the inventive arrangement of FIG. 1 in a perspective view.

FIG. 4 shows a series circuit for monitoring six bolt connections that are used for connection of three gradient coils, in accordance with the invention.

### DESCRIPTION OF THE PREFERRED EMBODIMENTS

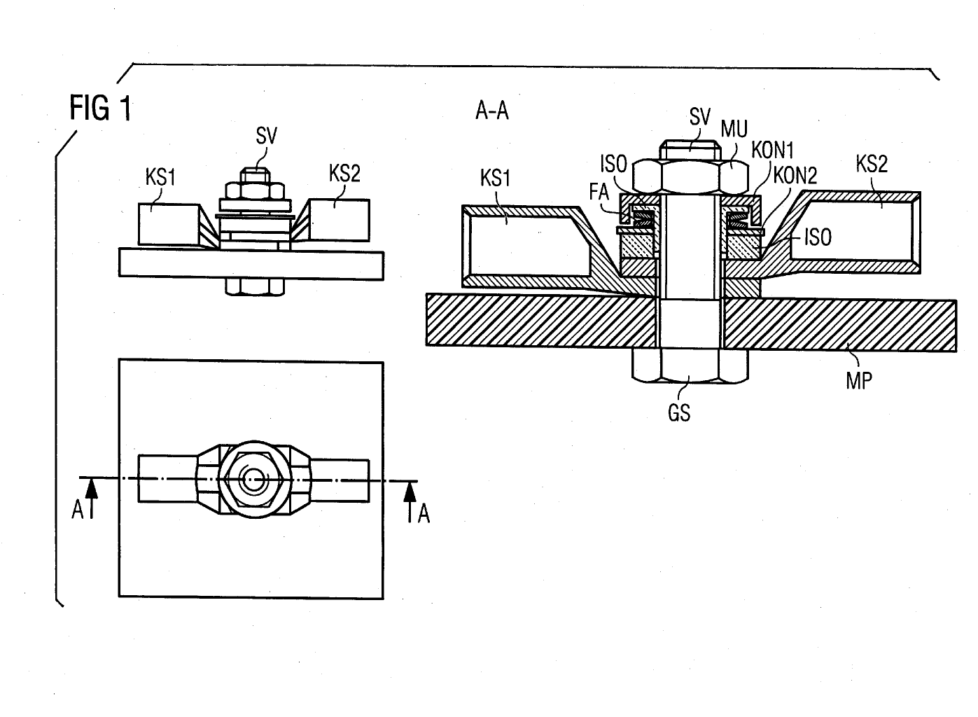

FIG. 1 shows an exemplary embodiment of the inventive arrangement with a loose bolt connection SV.

A cable (not shown) has at its end a first cable lug KS1 that is to be connected with a second cable lug KS2 of a further cable a bolt connection SV.

The bolt connection SV here is exemplarily fashioned with a threaded bolt GS, having a bolt head, and with a nut MU placed on the threaded bolt GS and interacting therewith. The bold head and the nut MU form retainers of the bolt connection SV.

A mounting plate MP with holes is exemplarily provided for a defined position of the bolt connection SV. Depending on the usage or intended use of the bolt connection SV, this mounting plate MP could be omitted.

The threaded bolt GS is directed on the threaded side through a hole of the mounting plate, through the first cable lug KS1 and through the second cable lug KS2 and can now be directly initially loaded and secured (fixed) by the nut MU.

A first contact KON1, a second contact KON2 and an insulator ISO are arranged between the second cable lug KS2 and the nut MU. The insulator ISO is designed or shaped such that it electrically separates both contacts KON1 and KON2 given an unsecure or loose bolt connection. For this purpose, the insulator ISO has a spring arrangement FA that holds the two contacts KON1 and KON2 at a distance from each other and thereby electrically separates them.

Only when the bolt connection SV exhibits a predetermined mechanical minimum tension, produced by nut MU and the threaded bolt GS, that is greater than the predetermined elastic tension of the spring arrangement FA, is an electrically-conductive connection established between the first contact KON1 and the second contact KON2 by compression of the spring arrangement FA. The bolt connection SV is then considered to be reliable or firm.

The spring arrangement FA is designed, for example, as a disk spring or as a disk spring assembly. Shown here is a spring arrangement FA designed as a disk spring packet that exhibits a V-shaped cross-section. A mechanical initial loading between the contacts KON1 and KON2 that ensures an open contact given a loose bolt connection SV is specifically set by this shape.

The mechanical initial loading of the spring arrangement FA is increased upon tightening of the bolt connection SV due to the shape of the spring arrangement FA. The mechanical initial loading simultaneously serves to secure the bolt connection SV because the spring arrangement FA has a high elasticity in comparison to the threaded bolt GS.

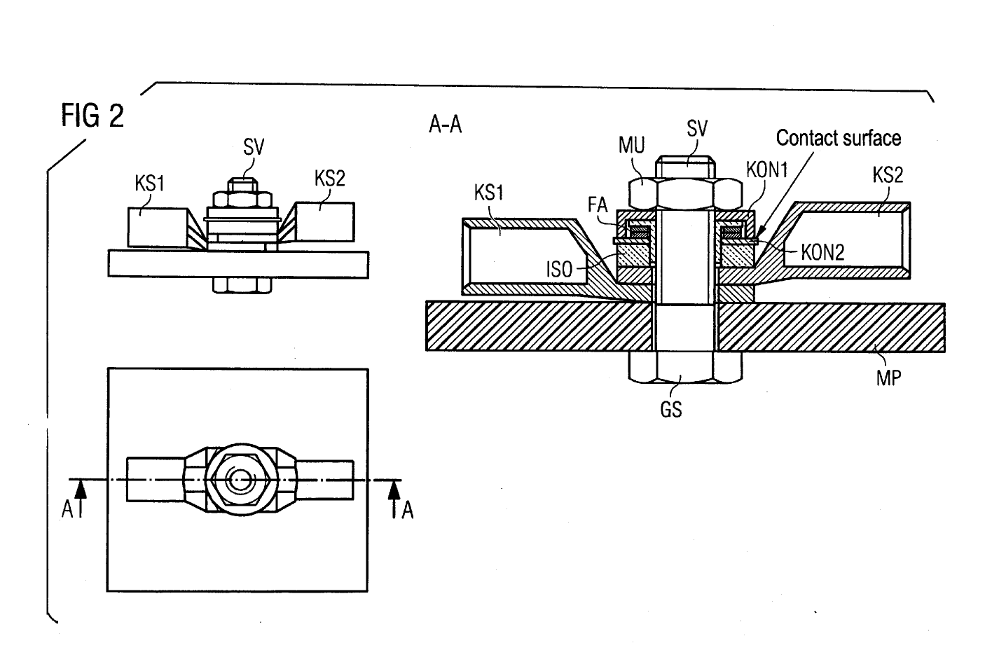

Related to FIG. 1, FIG. 2 now shows the inventive arrangement with tightened bolt connection SV.

By screwing the nut MU onto the threaded bolt GS, the two contacts KON1 and KON2 contact upon exceeding the defined mechanical initial load. An electrical contact or short between the two is thereby established that can be electronically detected and, if applicable, remotely monitored with little effort.

The V-shaped disk spring assembly of the spring arrangement FA shown in FIG. 1 is thus compressed counter to the defined mechanical initial load by the screwing of the nut MU on the bolt G5.

If the two contacts KON1 and KON2 are tightened past a first contact point, the initial load then also increases further, with the elasticity of the appertaining elements being determined by the bolt connection SV.

If the bolt connection SV is damaged or the bolt connection SV loosens, the spring arrangement FA (here the v-shaped disk spring assembly) would separate the two contacts KON1 and KON2 from one another (again) so that the unreliability of the bolt connection is indicated by the absent electrical contact.

The inventive arrangement can be used not only for monitoring during the mounting, but also during active apparatus operation.

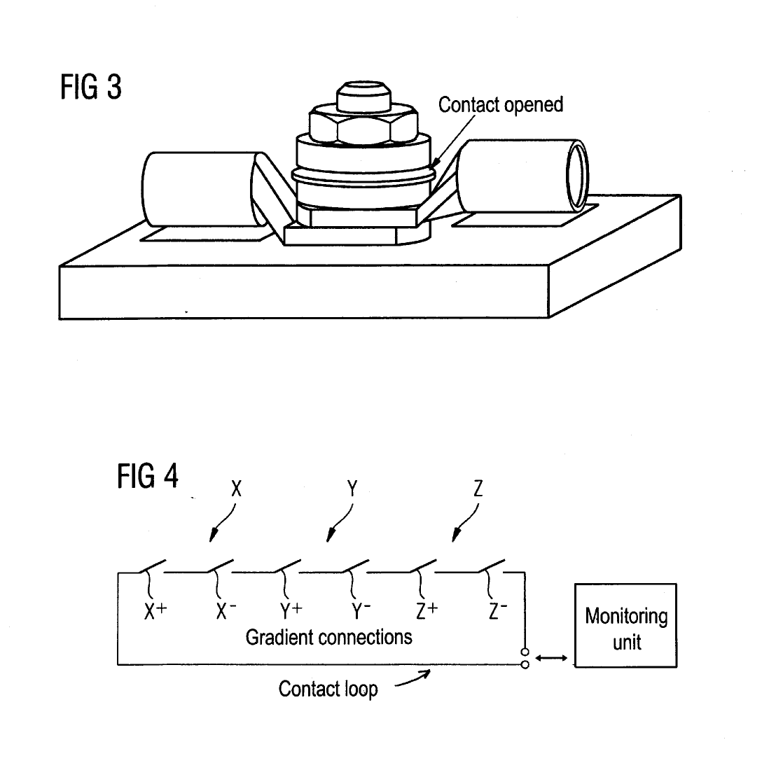

Related to FIG. 1, FIG. 3 shows the inventive arrangement with loose bolt connection in a three-dimensional (perspective) representation.

FIG. 4 shows a series circuit for monitoring of six bolt connections x+, x−, y+, y−, z+ and z− that are required for connection of three gradient coils x, y and z.

As described above, each of the bolt connections x+, x−, y+, y−, z+ and z− is monitored by two contacts per bolt connection, these two contacts forming a switch.

Six switches are thus connected in series for monitoring of the connections of the three gradient coils x, y and z, such that monitoring with a monitoring unit is easily possible by the contact loop thereby formed.

If the series circuit is high-impedance, no current may be switched on the gradient coils x, y and z.

By contrast, if the series circuit is low-impedance, all switches are closed, the mechanical minimum initial load is ensured and the current may be switched.

Although modifications and changes may be suggested by those skilled in the art, it is the intention of the inventors to embody within the patent warranted hereon all changes and modifications as reasonably and properly come within the scope of their contribution to the art.

We claim as our invention:

1. An arrangement for monitoring a bolt connection that connects a first component and a second component by holding said first and second components between two retainer elements of the bolt connection, said arrangement comprising:
an insulator comprising two electrical contacts;
a spring arrangement located between one of said retainer elements and the first or second component that is closer to said one of said retainer elements, said spring arrangement being located between said two electrical contacts and having a spring force that electrically separates said two contacts if said bolt connection is loose, and said first and second retainer elements overcoming said spring force, and maintaining said two contacts in electrical connection with each other by overcoming said spring force, given a firm bolt connection; and
a monitoring circuit in communication with said two contacts that indicates said firm bolt connection as long as said two contacts are in electrical connection with each other.

2. An arrangement as claimed in claim 1 wherein said first electrical contact is electrically conductively connected with said bolt connection, and wherein said second electrical contact is connected to said insulator via said spring arrangement.

3. An arrangement as claimed in claim 1 wherein said bolt connection comprises a bolt having a shaft with a bolt head thereon, and a fastener that interacts with said bolt shaft, said bolt head and said fastener forming said two retainer elements of said bolt connection.

4. An arrangement as claimed in claim 3 wherein said shaft is a threaded shaft and said fastener is a threaded nut on said threaded shaft.

5. An arrangement as claimed in claim 3 wherein said fastener is movable toward said bolt head to tighten said bolt connection, and wherein said two electrical contacts of said insulator are placed in electrical connection with each other upon tightening of said fastener to an extent that overcomes said spring force.

6. An arrangement as claimed in claim 1 wherein said spring arrangement is a spring arrangement selected from the group consisting of a disk spring and disk spring assemblies.

7. An arrangement as claimed in claim 6, wherein said spring arrangement has a V-shaped cross-section that sets an initial separation force between said two contacts to urge said two electrical contacts apart given said loose bolt connection.

8. An arrangement as claimed in claim 1 wherein said monitoring circuit is located at a location remote from said bolt connection.

9. An arrangement as claimed in claim 1 wherein said first component and said second component are electrically conductive cable lugs, and wherein said firm bolt connection places said cable lugs in electrical contact with each other.

10. An arrangement as claimed in claim 9 wherein said cable lugs that connect cables of a gradient coil of a magnetic resonance apparatus.
